(19) United States
(12) Patent Application Publication
(10) Pub. No.: US 2003/0086300 A1
(43) Pub. Date: May 8, 2003

(54) FPGA coprocessing system

(76) Inventors: Gareth Noyes, Abingdon (GB); Stuart Newton, Oxford (GB); John Alexander, Oxford (GB); Hammad Hamid, Berkshire (GB); Mat Newman, Oxford (GB)

Correspondence Address: DAVIDSON, DAVIDSON & KAPPEL, LLC, 485 SEVENTH AVENUE, 14TH FLOOR, NEW YORK, NY, 10018, US

(21) Appl. No.: 10/116,170

(22) Filed: Apr. 4, 2002

Related U.S. Application Data
(60) Provisional application No. 60/281,943, filed on Apr. 6, 2001.

(51) Int. Cl. G11C 5/00

(52) U.S. Cl. 365/189.01

(57) ABSTRACT

A system is provided which includes a host computing environment and a field programmable gate array (“FPGA”). The host computing environment includes a compiled software application which, in turn, includes a first plurality of functions and a second plurality of function calls. The FPGA is coupled to the host computing environment, and includes a compiled user function which is executed in response to one of the second plurality of function calls.

This application claims priority from U.S. Provisional Application Serial No. 60/281,943, filed Apr. 6, 2001, the entire disclosure of which is hereby incorporated by reference.

### BACKGROUND INFORMATION

Field Programmable Gate Arrays (FPGAs) are gate arrays which can be repeatedly reprogrammed while remaining in their environment of use (e.g., while mounted in the circuit board in which it is intended to be used). FPGAs typically include programmable logic blocks (e.g., programmable boolean logic gates), and may also include programmable memory blocks, programmable clocking blocks, and other specialized programmable blocks such as multiplier blocks and I/O ports. Examples of commercially available FPGAs include those manufactured and distributed by the XILINX, Inc., such as the Spartan Series and Virtex Series FPGA's.

Typically, FPGAs are programmed using a programming language specific to FPGA's, such as the Verilog HDL (Hardware Description Language) or the VHSIC HDL (often referred to as VHDL). These programming languages are generally used to implement specific hardware logic which is desired in the FPGA. As an example, the VHDL statement “ADD<=A1+A2+A3+A4” could be used to add signals A1 through A4. After the logic has been coded in HDL, it is compiled into a bit map. The FPGA can then be programmed by writing the bit map to the FPGA.

Recently, Celoxica has introduced The Celoxica™ DK1 design suite. This product utilizes Handel C, which is a C-based programming language which can be used to program FPGA's, and allows a designer to use C-based programming techniques to migrate concepts directly to hardware without requiring the designer to have any knowledge of hardware description languages (HDLs).

### SUMMARY

In accordance with a first embodiment of the present invention, a system is provided which includes a processor and a field programmable gate array (“FPGA”). The processor is coupled to a memory which includes a compiled software application which, in turn, includes a first plurality of functions and a second plurality of function calls. The FPGA is coupled to the processor, and includes a compiled user function which is executed in response to one of the second plurality of function calls.

In accordance with a second embodiment of the present invention, a method for executing a compiled software application is provided. In accordance with this method, a processor is provided which is coupled to a memory, the memory including a compiled software application. The compiled software application, in turn, includes a first plurality of functions and a second plurality of function calls and at least one of the second plurality of function calls corresponds to a compiled user function. The first plurality of functions and second plurality of function calls are executed on the processor and, in response to the at least one of the plurality of function calls, the compiled user function is executed on an FPGA which is coupled to the processor.

In accordance with a third embodiment of the present invention, a system is provided which includes a host computing environment, a host application program interface (API) on the host computing environment, an FPGA, and a client API on the FPGA. The host computing environment includes a compiled software application that includes a first plurality of functions and a second plurality of function calls. The FPGA is coupled to the host computing environment, and includes a compiled user function that corresponds to at least one of the plurality of function calls. The host API passes parameters for the compiled user function to the client API, requests initiation of the compiled user function, receives signals from the client API that indicate an end of execution of the user function, and retrieves return data from the user function via the client API. In contrast, the client API receives the parameters passed from the host API, forwards the received parameters to the user function, begins execution of the user function on the FPGA, and, upon the end of execution of the user function, configures the return data and transmits a signal the host API indicating the end of execution of the user function.

In accordance with a fourth embodiment of the present invention, a method for executing a compiled software application is provided. In accordance with this method, a host computing environment including a compiled software application is provided. The compiled software application, in turn, includes a first plurality of functions and a second plurality of function calls and at least one of the second plurality of function calls corresponds to a compiled user function. This method further includes the steps of, on the host computing environment, passing arguments for a compiled user function to an FPGA coupled to the host computing environment; requesting execution of the compiled user function, receiving a notification from the FPGA that indicate an end of execution of the user function, and retrieving return data from the user function via the FPGA. This method also includes the steps of, on the FPGA, receiving the arguments passed from the host computing environment, executing of the user function on the FPGA, and upon the end of execution of the user function, configuring the return data and transmitting the notification to the host computing environment indicating the end of execution of the user function.

In accordance with a fifth embodiment of the present invention, a system is provided which includes a host computing environment and an FPGA. The host computing environment includes a compiled software application that includes a first plurality of functions and a second plurality of function calls. The FPGA is coupled to the host computing environment, and includes a plurality of compiled user functions. A first one of the plurality of compiled user functions is executed in response to one of the second plurality of function calls, and a second one of the plurality of compiled user functions is executed in response to an instruction from the first one of the plurality of compiled user functions.

In accordance with a sixth embodiment of the present invention, a method for providing an interface between a processor and an FPGA is provided, the processor being operable to execute a compiled software application, the compiled software application including a first plurality of functions and a second plurality of function calls, at least one of the second plurality of function calls corresponding to the compiled user function. The method comprises the steps of: passing arguments for a compiled user function to a Field Programmable Gate Arrary (FPGA) coupled to a processor, requesting execution of the compiled user function, receiving a notification from the FPGA that indicates an end of execution of the compiled user function, and retrieving return data from the compiled user function via the FPGA.

In accordance with a seventh embodiment of the present invention, a method for providing an FPGA interface to a processor is provided, the processor being operable to execute a compiled software application, the compiled software application including a first plurality of functions and a second plurality of function calls, and at least one of the second plurality of function calls corresponding to a compiled user function on an FPGA. The method comprises the steps of, on the FPGA, receiving arguments for a compiled user function from the processor, passing at least a portion of the received arguments to the compiled user function, and upon receiving an indication of an end of execution of the compiled user function, configuring the return data and transmitting a notification to the processor indicating the end of execution of the compiled user function.

In accordance with other embodiments of the present invention, computer readable media are provided which have stored thereon, the computer executable process steps described herein.

### BRIEF DESCRIPTION OF THE DRAWINGS

FIG. 1(a) shows three illustrative configurations of a host computer coupled to an FPGA.

FIG. 1(b) shows a host computer coupled to an FPGA, wherein the FPGA is configured as a transmitter and receiver of streaming data.

FIG. 1(c) shows a host computer closely coupled to an FPGA, wherein the FPGA is coupled to a downstream DSP.

FIG. 2 illustrates an execution flow between a host computer and a closely coupled FPGA.

FIG. 3 shows an exemplary software architecture for the CPUs and FPGAs of FIG. 1.

FIGS. 4(a) and 4(b) is an illustrative flow chart for the execution fo a function call from a host computer to a closely coupled FPGA.

FIG. 5 is an exemplary flow chart for and Execute and Wait type function call.

FIG. 6 illustrates an exemplary software architecture for a host API.

### DETAILED DESCRIPTION

Recent developments have made high level languages suitable for programming hardware devices. In this regard, compilers have now been developed that can generate gate-level code suitable for programming FPGAs from code written in “C” (or C-like languages). To date, these compilers have been used as alternative methods of specifying hardware logic. In other words, they have been used essentially as an improved interface (as compared to HDLs) for programming hardware logic.

The inventors of the present application have recognized that, through the use of such high level programming to hardware device compilers, software functions traditionally written with the intention of compiling them to be run on a CPU can be migrated to run on a closely coupled FPGA or other similar hardware devices.

In accordance with the embodiments of the present invention described herein, a framework is provided that allows designers to migrate software functions from applications running on a CPU to an FPGA in a transparent manner. This technology allows CPUs to make a function call that is actually processed and run in hardware, with the FPGA acting as a re-configurable sub-processor. This allows developers to take a systems view of their application software and to optimize their application software by selecting whether functions are executed in hardware or in software. The benefits of such an architecture include an increase in systems performance by freeing up the processor to carry out other tasks and delivering true parallel processing, and by decreasing the execution time of the functions themselves through implementation in hardware rather than software. An example of such an application would be to implement a graphics library (such as the WindML graphics library used in the Vx Works® operating system manufactured by Wind River Systems, Inc.) directly in an FPGA while allowing the programmers to use the same API that normally utilizes a conventional software graphics library. In this regard, a portion of a graphics library could be implemented in an FPGA, while the remaining portion of the library is implemented in software. From the perspective of the API accessing the library, however, there would be no difference between the two portions.

Traditionally developers have had to design systems consisting of multiple CPU devices to achieve similar performance, or design hardwired ASICs to perform optimized tasks. Moreover, in addition to enabling new designs, the above-referenced framework allows designers to optimize legacy source code previously written for CPUs to be used in a mixed hardware/software environment.

The architecture described below provides a framework which allows a software developer to prepare a single, integrated application (for example, in a C programming language), and, to have one portion of the application implemented in software and another portion of the application implemented on an FPGA, simply by compiling one portion of the application into software object code and the other portion of the application into an FPGA bit map. In this regard, the software developer need not be concerned with the specifics of how this partition is implemented, or with the interface which allows the CPU and FPGA implemented portions to communicate with each other.

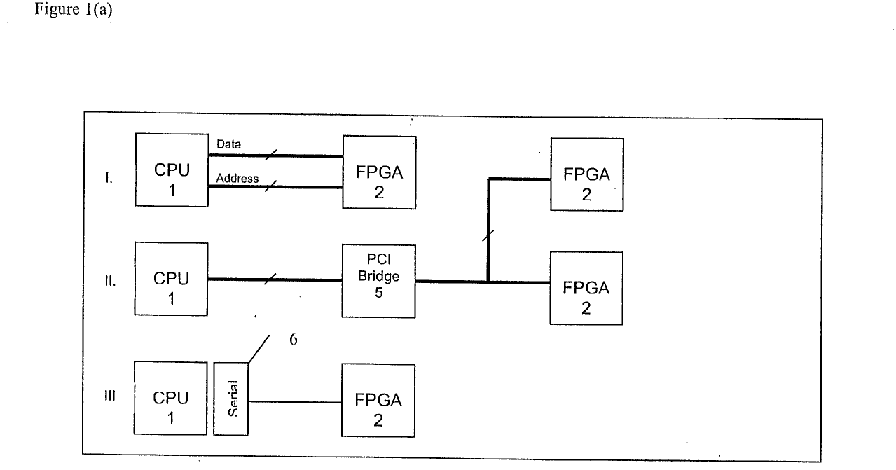

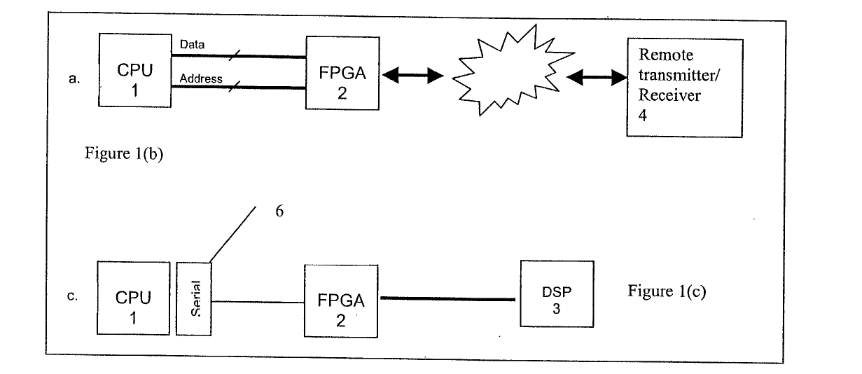

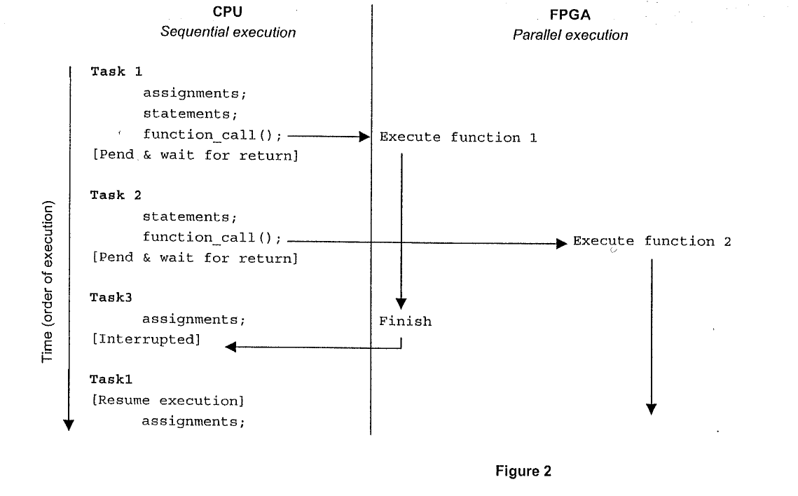

In accordance with an embodiment of the present invention, a system is provided which includes a processor and a closely coupled FPGA which is addressable from the processor. Examples of such “closely coupled” arrangements include FPGAs connected directly to the processor's memory bus (e.g., fabricated on the same chip as the processor) or accessible via intermediate buses, for example via PCI. A plurality of FPGAs could be accessible from a single processor, or shared among multiple processors. Referring to FIG. 1, examples of closely coupled processor-FPGA configurations include FPGAs 2 coupled to CPUs 1 via (I) Direct memory access, (II), PCI Bus 5, or (III) serial connection 6.

In the context of the present invention, the term processor is meant to broadly encompass any device which is capable of executing machine code instructions, including without limitation: a host computer (or host computing environment), a CPU, a CPU integrated into an FPGA (e.g., on the same silicon die), a “soft core” (e.g., a processor emulated on an FPGA), etc. Moreover, in the context of the present specification, the terms “host computer” or “host computing environment” are interchangeable, and are meant to encompass any processor which is coupled to a remote FPGA (e.g., an FPGA on a separate silicon die from the processor), including, without limitation, embedded processors, computer workstations, computer servers, desktop computers, hand held computers, etc.

Coprocessing FPGA 2 can also be used as a transmitter and/or receiver of streaming data (such as video, audio, and other data). For example, referring to FIG. 1(b) an I/O port of the FPGA 2 could be coupled to a source of incoming streaming data from a remote transmitter 4, and the decryption and decompression functions normally implemented in application software on the host computer 1 could be compiled into the FPGA 2 as a bit map (“.bit”) file. The decrypted, decompressed data would then be passed transparently to the application programs executing on the host computer. The same (or a separate) I/O port of the FPGA 2 could similarly be used as a transmitter by compiling the encryption and compression functions (which are normally implemented in application software on the host computer 1) on the FPGA 2.

The coprocessing FPGA could, itself, also be coupled to other downstream processing devices. For example, the coprocessing FPGA could be coupled to a downstream digital signal processor (DSP) as illustrated in FIG. 1(c). In such an embodiment, the FPGA 2 could itself off-load digital signal processing applications (e.g., processing of video or sound data) to a DSP 3.

Multitasking operating systems such as Vx Works® provide a framework that allows programmers to structure their applications with the appearance of many things occurring at once (pseudo parallelism). This is achieved by grouping a series of statements, assignments and function calls under the umbrella of a discrete, schedulable entity referred to as a task. When executing on a single CPU, only one task is active at any one time. Therefore, offloading functions onto a co-processor frees up the CPU to perform other tasks, and often allows those functions to execute more quickly. An advantage of using an FPGA as a co-processor is that functions are not implemented through sequential execution of instructions, as is the case for a CPU, but in hardwired logic gates programmed to achieve specific and optimized functionality. This architecture allows for several functions to execute concurrently, with a resulting increase in possible throughput.

It should be noted, however, that even in non-multitasking software applications (i.e., single thread applications), the use of a FPGA coprocessor in accordance with the present invention allows an increase in performance because an FPGA can usually execute a function faster than the CPU can execute the same function. In addition to allowing many functions to execute in parallel, and more quickly, coprocessor FPGAs also provide the advantage of being reconfigurable.

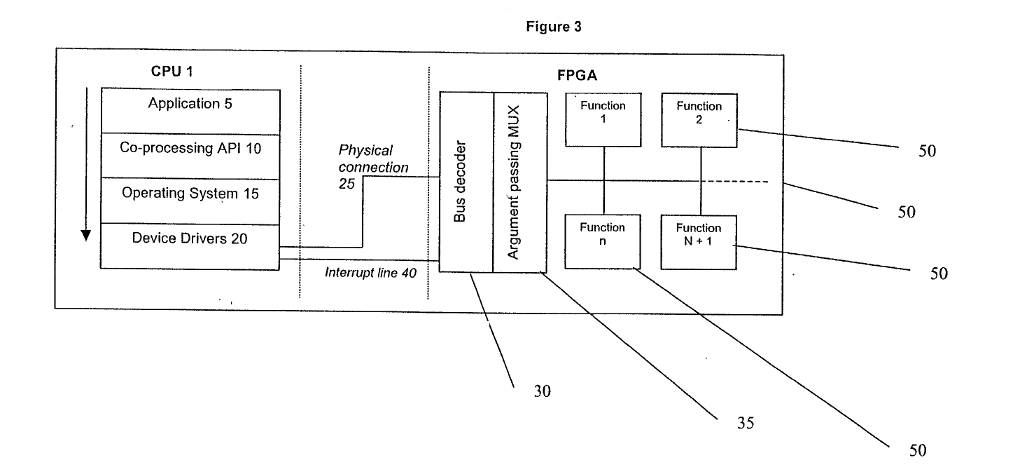

FIG. 2 illustrates the use of an FPGA coprocessor in a multi-tasking environment. The host computer begins in a Task 1 and executes a function call to function 1. However, since function 1 is implemented in an FPGA, Task 1 is pended, awaiting the return of the function 1. While the FPGA is executing function 1, the host computer is free to begin execution of Task 2. During execution of Task 2, the host computer executes a function call to function 2. Function 2, in turn, is executed in the FPGA concurrently with function 1, and the host computer begins execution of Task 3. When the FPGA returns function 1 to the host computer, the host computer interrupts execution of Task 3, and resumes execution of Task 1.

The co-processing functionality of the FPGA can be programmed from high-level languages as a set of functions (hereinafter “user functions”). User functions can be called concurrently in a variety of ways, including multiple instantiation of functions in the FPGA, and implementation of pipelined functions through appropriate hardware design. In order to provide transparency, an interface layer can be provided in the operating system to pass arguments to the user function executing in the FPGA, to receive arguments from the FPGA, and to return these arguments to the program executing on the host computer. Such an interface layer allows easy migration of functions from the host computer to the user functions in the FPGA.

Preferably, the co-processing functionality is provided by a set of APIs (Application Program Interface or Application Programming Interface) on both the host computer and the FPGA. The APIs can be separated into several functional blocks executing on either the host computer or the FPGA.

In this regard, the CPU (host side) API: passes arguments to the user function on the FPGA; requests initiation of the user function; receives signals from the FPGA (client side) API notifying it of the end of execution of user function; and retrieves returned data from the user function. The FPGA API, in contrast, receives the arguments from the CPU API and forwards them to the user function being called; begins execution of the user function; and upon completion of the user function, sets up return arguments and signals the host computer that a function has completed

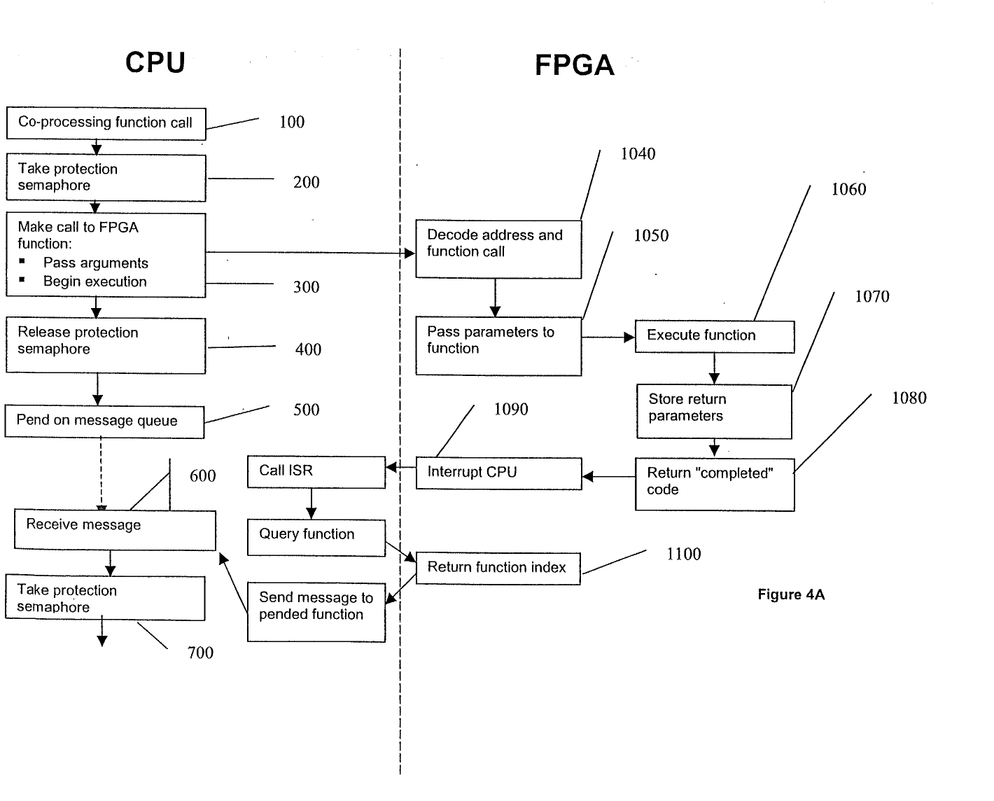

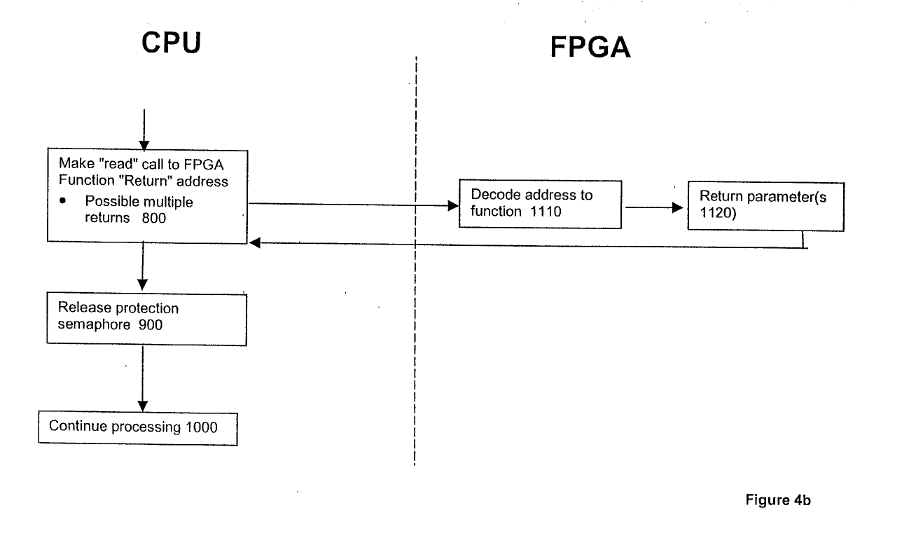

FIGS. 3, 4(a) and 4(b) illustrate such a process. When the CPU API 10 receives a function call from a task (for example, as part of an application 5) which includes a user function assigned to an FPGA 2 (step 100), the CPU API 10 invokes a suitable protection mechanism (in this case, takes a semaphore) (step 200). The CPU API 10 then makes a call to the FPGA API, passing the arguments of the function and requesting intiation of the function (step 300). The call to the FPGA API is propagated through the appropriate device drivers 20 (via operating system 15) and to the FPGA 2 via physical connection 25, which can include, for example, a bus architecture that allows addressing of components attached to the bus (in this case, FPGA 2). The CPU API 10 then releases the protection mechanism (e.g., giving the semaphore) (step 400), and pauses execution of the task by pending the task on the message queue (step 500) of the host computer 1. At this point, the host computer 1 is free to execute other tasks while awaiting a return of the function call.

In any event, immediately following step 300, the FPGA 2 decodes the function call in the FPGA API 35 (step 1040). If the FPGA 2 is coupled to the CPU 1 via a bus, the FPGA 2 may first decode the address propagated over physical connection 25 with bus decoder 30 (e.g., to determine that the device driver's message is for that FPGA). In any event, after the arguments from the function call are decoded, the arguments required by the function are passed to the user function 50(e.g. function 1) on the FPGA 2 (step 1050). The user function is then executed (step 1060), the return arguments stored (step 1070) on the FPGA, and a return code is sent to the FPGA API (step 1080). The FPGA API then sends an interrupt to the CPU API 10 (step 1090) via interrupt line 40 (which forms a part of physical connection 25) and device drivers 20, and the CPU API 10 executes an ISR (interrupt sub-routine) call. The CPU API 10 then sends a query (step 1020) to the FPGA API (via physical connection 25) to determine which user function on the FPGA 2 has caused the generation of the interrupt. The FPGA API then returns a function index (e.g., an address for the user function 1 which is known to the CPU API) to the CPU API 110. The CPU API 110 then sends a message to the pended function (step 1030). Once the message has been received (step 600), the CPU API 10 takes the semaphore (step 700) and makes a read call to the return function address indicated in the function index. In step 11110, the FPGA API 10 then decodes the address provided in step 800, and returns the arguments (previously stored in step 1070) to the CPU API 10. After all of the arguments have been returned, the CPU API 110 releases the semaphore protection (step 900), and the task continues processing. It should be noted that multiple occurrences of the read calls (e.g., repeating steps 800, 1110, 1120) may be executed after a single ISR. It should be appreciated that although the FPGA 2 preferably uses an interrupt signal to notify the CPU 1 that a user function has been completed, alternative methods of notification could also be used. For example, the CPU 1 could periodically poll the FPGA 2 to determine when a user function has been completed.

An important advantage of the CPU API implementation described above is that it frees up the host computer for other uses while a user function is executing. This is achieved by pending a task while awaiting completion of a co-processing function, as illustrated above with reference to FIG. 4(a,b). Naturally, this feature could also be disabled to provide an ‘in-line’ function call.

In order to implement the above functionality, a common set of interfaces is defined between the APIs residing on the host computer and those residing on the FPGA. In this regard, a protocol is established for passing arguments to user functions inside the FPGA. Although a wide variety of approaches could be used, one approach would be to relate addresses memory mapped to the FPGA to specific function calls so that, for example, a write operation to address 0×100 could instruct the FPGA to start receiving arguments for user function 1. Successive writes to the same address would then refer to the first, second, third argument and so on. The read location of the same address could be used for passing return arguments. Another approach would be to use a single address for message passing with a suitable protocol defined for passing function calls and arguments. The former approach is the most flexible, as it would allow compilers to generate most of this setup information automatically (equating addresses to functions that need to be invoked). Other schemes are also possible.

An illustrative implementation of the CPU and FPGA APIs will now be described in detail.

In accordance with certain embodiments of the present invention, call-back functions can be used to implement an event driven system for communicating between the host computer and the FPGA. Call-back functions are executed to inform the user application (i.e., the application 5 running on the host computer 1) when events have occurred. In this regard, multiple call-back functions may be executed for a single user function, or for a single event. Data can be transferred to a call-back function in the form of a results structure. As described below, examples of such call back functions could include an ExecuteFunctionWait( ) function, or for more advanced and overlapped remote function execution, using ReadData( ) and WriteData( ) functions. In general, the last event to be signaled before a data transfer is completed would normally be a completion status report or a fatal error.

It should be noted that when a function call is made on a processor, data is usually sent to the processor, and when the execution of the function is completed, data is often returned from the function. Although use similar concepts of data passing can be used when executing a task on an FPGA co-processor (e.g., the ExecuteFunctionWait( ) function described herein), data transfers on an FPGA coprocessor need not be limited to transfers occurring at the start and end of the task. Rather, data can be transferred to and from a user function at any time (e.g., using ReadData( ) and WriteData( ) as described herein), thereby providing much more flexibility in using the FPGA coprocessor. The timing of the transfers is only limited by the design of the user function itself.

The ExecuteFunctionWait( ) function could, for example, conform to the following syntax:

TransferResultsStructure ExecuteFunctionWait(unsigned int FunctionIndex, unsigned int DataAmountParameters, char *ParameterDataBuffer, unsigned int ReturnDataAmount, char *ReturnDataBuffer);

wherein FunctionIndex is the Index (e.g. address) of the user function to be executed in the FPGA, ParameterDataBuffer is the data buffer which contains the arguments to send to the user function to be executed, DataAmountParameters is the size of the argument data buffer (ParameterDataBuffer) in bytes, ReturnDataBuffer is the data buffer used to store the return data from the user function to be executed, and ReturnDataAmount is the size of the return data buffer in bytes.

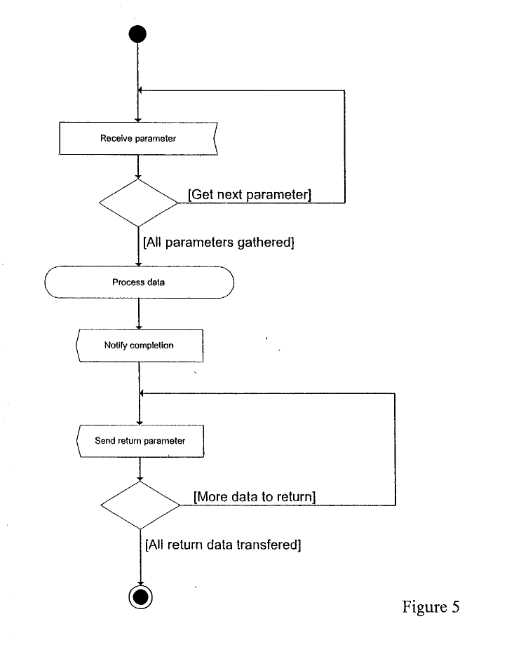

The data returned by the ExecuteFunctionWait( ) function (in the ReturnDataBuffer) will contain information about of the completion of the user function execution on the FPGA including, for example, the results of the function call, or an error message. The ExecuteFunctionWait( ) function can be used for FPGA user functions in which all of the arguments required by the user function are received in the FPGA before the user function is executed in the FPGA. A general flowchart for a user function which can be executed in an FPGA in response to the ExecuteFunctionWait( ) function is shown in FIG. 5 including the steps of i) gathering the arguments transmitted to the FPGA, ii) processing the data; iii) notifying the CPU API of the completion of the function; and iv) sending the return data to the CPU API.

Preferably, a suitable syntax is also provided for configuring (or reconfiguring) the FPGA from applications running on the CPU 1. As an example:

int ConfigureCoprocessor(char *BitFile),

wherein BitFile is a name of of a ‘.bit’ file to be loaded into the FPGA co-processor, could be used to configure the FPGA 2.

A wide variety of protocols could be used to execute functions on the FPGA. In general, application programs on the host computer 1 will use the CPU API to execute functions on the FPGA 2. The FPGA will receive the messages from the host computer 1 (via device drivers 20) and stream data via the FPGA API to and from its user functions as required. The user functions will interact with the FPGA API to access FPGA resources. For example, the CPU API will request initiation of a user function, send arguments to the user function, retrieve data from the user function, and receive data ready notifications from the FPGA API. The FPGA API, in contrast, executes a user function when instructed to do so, passes data to a user function as required, passes data from a user function as required; sends data ready signals to the CPU API; and provides the address of the user function that generated a data ready signal to the CPU API. Both the CPU and FPGA APIs may also perform other auxiliary functionality associated with diagnostics, housekeeping, initialization, reconfiguration of the FPGA, etc.

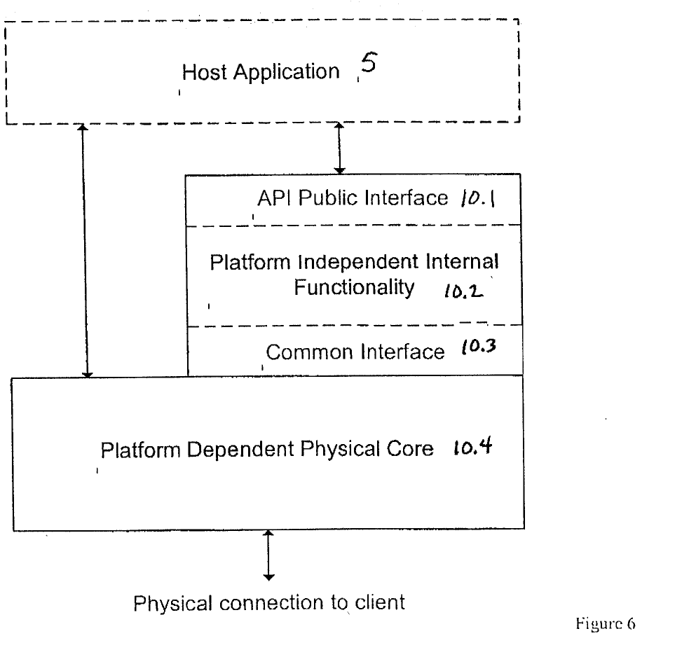

In certain embodiments of the present invention, the CPU and FPGA APIs can each be organized as a multiple layer architecture in order to provide a platform independent abstract interface layer for interfacing with the application software on the host computer. With such an architecture, it is not necessary for the applications executing on the host computer to have any knowledge of the protocols used by the host and client to communicate. It is only necessary for these applications to have knowledge of the protocols of the abstract interface layer, which can be generic to any CPU and any FPGA. FIG. 6 illustrates a CPU API with such an architecture. In this regard, the CPU API 10 is shown having an application software layer 5 (e.g., host application software compiled, for example, in C). Below the application software layer 5 is the CPU API 10 including a platform dependent physical core layer 10.4 (PDPC) (e.g., including platform specific functionality for communicating with the FPGA), an API public interface 10.1, platform independent internal functionality 10.2 (PIIF), and a common interface 10.3. The API public interface is the interface to the host application and is platform independent. In this regard, the protocols used in this interface are independent of the CPU, FPGA, and other hardware used. Instructions received from the host application via the API public interface are processed in the PIIF, and where appropriate, instructions are sent to the PDPC for transmission to the FPGA. With this architecture, any platform specific modifications can be dealt with by simply modifying the common interface (if necessary), without affecting the remaining layers.

Examples of instructions which are implemented by the API public interface may include, for example, the ExecuteFunctionWait( ) function described above. Other functions implemented though this interface might include a StartCoprocessorSystem( ) function to initialize the API and allocate system resources, and a ShutdownCoprocessorSystem( ) function to provide an orderly shutdown of the API.

It should be noted that the architecture shown in FIG. 6 also allows the host application to directly access the PDPC. Therefore, it should be appreciated that functions implemented by the physical layer interface may be invoked either by a host application directly or through the common interface from the API Public Interface and PIIF.

Examples of functions implemented in the PDPC include the ConfigureCoprocessor(char *BitFile) described above. Other functions might include a ReadData, WriteData, and QueryTransaction function. In this regard, in order to allow transferring of data from an FPGA, the following syntax can be used: unsigned int ReadData(TransferConfiguration Configuration), wherein “Configuration” is a structure that contains all the required data to begin the operation. The return value from this function is a unique identifier for the operation (in this case in the form of an unsigned integer value), which can be used for informative communication. To transfer data to an FPGA, the following syntax can be used: unsigned int WriteData(TransferConfiguration *Configuration), wherein “Configuration” is a structure that contains all the required data to begin the transfer. The return value is a unique identifier for the transaction (in this case in the form of an unsigned integer value).

In this regard, the Configuration structure, provides encapsulation for the configuration data may have the following syntax:

struct Configuration{

void (*TrasferCallback)(TransferResultsStucture
TransactionInformation);
unsigned int DataQuantity;
unsigned char *DataBuffer;
unsigned int DestinationAddress;
unsigned int MaxDesiredTransactionTime;

}

wherein DataQuantity is the amount of data (in bytes) to be transferred; DestinationAddress is the index of the function to which the data is to be transferred; MaxDesiredTransactionTime is the maximum desired time for a transaction in milliseconds, and DataBuffer is a pointer to a data buffer. In the case of a ReadData( ) function, DataBuffer is a pointer to the data buffer where the CPU API expects to find the data after the ReadData( ) function returns. Therefore, DataBuffer should be at least as big as DataQuantity bytes for a ReadData( ) function. In the case of a DataWrite( ) function, DataBuffer is a pointer to a data buffer which contains the data to be transferred to the FPGA. In the case of a DataWrite( ) function, DataBuffer can be smaller than DataQuantity bytes because the CPU API can stream data into the data buffer during the write operation.

Void (*TransferCallback)(TransferResultsStucture TransactionInformation), in turn, contains information regarding the status of a transfer. In this regard, the status results for a particular function are encapsulated in the TransferResultsStructure:

struct TransferResultsStructure{

unsigned int UniqueIdentifier;
unsigned int QuantityOfDataTransferred;
TransferResultsCodes ResultCode;

}

wherein QuantityOfDataTransferred is the number of bytes that successfully transferred, ResultCode is one of the defined states for the enumerated data type TransferResultsCodes (e.g., completed, failure, timeout, on hold, in progress, system busy). TransactionInformation, in turn, may include information regarding the reason for the call back function. The transfer call back function (TransferCallback(TransferResultsStucture TransactionInformation)) is used as the event handler for a transaction. The user can provide this function if, for example, they desire overlapped co-processor operations (e.g., using the ReadData( ) and WriteData( ) functions described above).

If a user application wishes to monitor the progress of an active transaction, a QueryTransaction function with, for example, the following syntax can be used: TransferResultsStructure QueryTransaction(unsigned int UniqueIdentifier), wherein UniqueIdentifier is used to provide a unique handle for each transaction. The return value of this function is a structure returned from this function which contains information about the transaction being queried.

Similar to the CPU API, the FPGA API can be divided into two sections: a User Functionality portion (which is a platform independent portion of the API) and a Physical Core Functionality portion (which is the platform dependent portion of the API). The User Functionality portion of the API (hereinafter UF portion) is platform independent so that users can implement platform independent functions which interact with the UF portion. The Physical Core Functionality portion (hereinafter PCF portion) manages any feature of the API that may be platform dependent, such as pin definitions, clock domain crossing, ram access and host interfacing. With this architecture, a developer should be able to transfer an FPGA API to another platform without modifying the UF portion of the API.

The UF portion of the API may, for example, implement an AssociateFunction(FunctionIndex, FunctionPointer) macro, wherein the FunctionIndex is the index that will be used by the host computer to transfer data to the user function being configured, and the FunctionPointer is a pointer to the user function that is being associated with the specified index. The UF portion of the API may also implement various macros which initialize function pointers, set various clocks, etc. As one of ordinary skill in the art will appreciate, while these instructions are described herein as implemented as macros, they could alternatively be implemented, for example, as compiled software.

When a user function is executed, a pointer to a structure is passed to the user function that contains pointers to various user API functions. The API functionality is provided in this way to allow user functions to be unaware that they are operating in a shared system. In this manner, there can be many user functions trying to send a notify to the host or trying to access shared memory, and each user function can operate as if it had an exclusive control. This structure (struct UserAPI) may, for example, have the following syntax:

struct UserAPI{

void(*SetAddress)(unsigned int 32 Address,
unsigned int 1 ReadOrWrite);
void(*DoTransfer)(unsigned int 32 *Data);
void(*GetData)(unsigned int 32 *Data);
void(*SendData)(unsigned int 32 Data);
void(*NotifyDataReady)( );
unsigned int 1 (*CheckForPost)( );
unsigned int 32 (*GetSendersAddress)( );
void(*SetPostAddress)(unsigned int 32 Address);
void(*DoPostDataRead)(unsigned int 32 *Data);
void(*DoPostDataWrite)(unsigned int 32 Data);

};

The SetAddress function is used to initiate a memory data transfer. It allows an address to be set via the Address argument, and the direction of the transfer to be configured via the ReadorWrite argument. The DoTransfer function is used to perform the data phase for a memory access operation. It automatically synchronizes with the address phase (SetAddress). The Data argument is a pointer to a register which is either written to or read from depending on the mode (ReadorWrite) selected during the preceding SetAddress function. In the illustrated embodiment, memory access is pipe-lined and it takes more than one clock cycle for a transaction to be completed. Separation of the address and data phase allows burst mode transactions to be performed. In other words, a single SetAddress function can be followed by multiple DoTransfer functions, eliminating the need to specify an address each time a transfer is initiated.

The GetData function is used by a user function to retrieve data from the host, and the Data argument is a pointer to the register which is to be loaded with the data from the host. This function will block until the host sends data. Similarly, the SendData function is used by a user function to send data to a host. The Data argument for this function contains the data to be sent to the host. This function will block until the host requests data from the user function.

The NotifyDataReady function is used by a user function to notify the host that data is ready. In this regard, the function issues some form of notification (such as an interrupt signal) to the host. However, this signal may be queued if other user functions are issuing NotifyDataReady functions at the same time.

The UserAPI structure defined above also includes various functions relating to mailbox functions. A mailbox can, for example, be implemented as a pair of registers. One register can be used for sending mail and the other for receiving mail. A flag can be used to indicate when new mail has arrived. A user function can monitor the flag to determine when mail has arrived. If after a read of the mailbox the flag is still set then new mail has already arrived (assuming that the flag is an active high signal). In this regard, a CheckForPost function can be used by a user function to test for the presence of data in the mailbox and a GetSendersAddress can be used by a user function to obtain the address of the sender of the data currently in the mailbox. The GetSenderAddress function is called in parallel with or before the DoPostDataRead function which reads the data from the mailbox. The SetPostAddress function can be used to initiate the sending of data. This function specifies a mailbox address of a recipient, and is used in conjunction with the DoPostDataWrite function which sends data to the previously specified address.

In addition to the User API functions, the illustrated system also includes a set of macros which implement Auxiliary I/O. Auxiliary I/O in turn, can be used, for example, to transmit and/or receive streaming data, to communicate with downstream DSPs, or other FPGAs.

The Auxiliary I/O macros are used to establish the links between a user function and auxiliary I/O. This allows a user function direct access to auxiliary I/O with no interference from the core of the client API. This direct access is believed to be advantageous because the nature of the devices connected to auxiliary I/O is usually unknown to the API. I/O ports are named and built into the libraries for the specific FPGA platform. Generally, Auxiliary I/O has no sharing mechanism, and therefore when a port is used by a user function, the user function has exclusive access to the port. If shared access to auxiliary I/O is desired, a service function should be designed that provides the sharing mechanism. The mailbox system described above can then be used for the sharing user functions to communicate with the service function.

In accordance with another aspect of the above embodiments, a user function can be provided with the ability to interact directly with other user functions within the FPGA without accessing the host.

For example, user functions can send messages to other user functions. This feature can be implemented, for example, using the mailbox feature described above. To use the mailbox feature for inter-user-function communications, an originating user function could simply be provided with the address of the destination user function.

In accordance with another aspect of the above embodiments, a user function can be provided with the ability to perform host type operations. A host operating mode can be implemented using the mailbox delivery system described above, and by providing a corresponding address for host-type user function operations (e.g. address 0). For example, a user function could send a SetPostAddress (0) function (e.g. using 0 as the Address argument) to indicate that it was initiating a host-type operation. The data subsequently transmitted with the DoPostDataWrite(Data) function could then represent the index of the user function that will receive communication. Once this posting has been sent, subsequent SendData and GetData functions will be re-directed to the specified user function. To restore normal operation of the SendData and GetData functions a message could be posted to address zero with the data set to zero.

This architecture could also be extended to allow a Function in one FPGA to perform host-type operations on another FPGA. To implement this, the MSB (most significant bit) of the data sent in the DoPostDataWrite(Data) could be used to indicate whether the Function is initiating a local host-type operation (i.e., in its own FPGA) or a remote host-type operation (i.e., in another FPGA).

In accordance with certain embodiments of the present invention, an FPGA may include multiple instances of the same user function. In such an embodiment the host (e.g. CPU) API may include a functions access database, wherein the functions access database includes, for each user function, availability information indicative of an availability of the user function. Preferably, the functions access database includes, for each user function, a function index field (e.g., the address of the user function on the FPGA, or information indicative thereof), a function type field (e.g. information indicative of the user function, such as the user function name), and an availability field (e.g., indicating whether the user function at the function index is available). With such a database, the CPU API will have knowledge of how many user functions of each type are on the FPGA, and can arbitrate access. For example, if there are two instances of a user function 1 on an FPGA, then the CPU API will allow a first request for function 1 to be directed to the address of the first instance of function 1, send the second request for function 1 to the address of the second instance of function 1, and to suspend any third simultaneous request for function 1.

As an example, consider the functions access database set forth below, for an FPGA having two User Function A's, two User Function B's, two User Function C's, and one User Function D.

| FPGA Address | User Function Type | Availability |
|---|---|---|
| 001 | Function A | Y |
| 002 | Function A | Y |
| 003 | Function B | N (e.g., semaphore taken) |
| 004 | Function B | Y |
| 005 | Function C | Y |
| 006 | Function D | Y |
| 007 | Function C | N |

Upon receiving a request for Function A, the CPU API interrogates the functions access database to determine if a first Function A is available, and since it is, it sends the request for the function A to the first instance of Function A on the FPGA (at address 001), takes a semaphore for the first instance of Function A and updates the functions access database accordingly. When a second request for Function A is received, the CPU API checks the access database again, but now sees that the first instance of Function A is not available. The CPU API then checks the second instance of Function A, sees that it is available, and sends the request for function A to the second instance of Function A on the FPGA (at address 002), takes the semaphore for the second instance of Function A, and updates the functions access database accordingly. If a third request for Function A is received, the CPU API will find that both the first and second instances of Function A are unavailable, and will therefore pend the request for Function A until one of the instances of Function A become available.

Upon receiving an indication that the first (or second) instance of Function A has terminated on the FPGA (e.g., the first instance of the user Function A has completed), the CPU API will return the semaphore for the first (or second) instance of Function A, and update the functions access database accordingly.

In the table above, availability is indicated as a Y/N value. However, it should be appreciated that the table could alternatively include the actual value of the protection mechanism being used to determine availability.

In certain embodiments of the present invention, CPU API may create the functions access database by interrogating the client (e.g., FPGA) API to determine what functions are available on the FPGA. In this regard, for example, the CPU API may send a request to the FPGA API, and the FPGA API may respond with a list of functions that are available on the FPGA and their corresponding addresses. Alternatively, the functions access database can simply be independently created based upon information known at the time the FPGA is programmed. In cases in which the FPGA is programmed via commands through the CPU API, the CPU API could generate the functions access database itself. If the FPGA is pre-programmed, the functions access database could be created by the user.

In certain embodiments of the present invention, the CPU API may be allowed to simply request the address of a function from the functions access database, bypass the protection mechanisms, and simply send the request to the FPGA API. In such a case, however, there is a risk that the user function will be unavailable.

Although the system and methods described above are preferably implemented in connection with FPGAs, it should be appreciated that other types of gate arrays may alternatively be used, including for example, non-reprogrammable gate arrays.

In accordance with other embodiments of the present invention, computer readable media are provided which have stored thereon, the computer executable process steps described above.

In the preceding specification, the invention has been described with reference to specific exemplary embodiments thereof. It will, however, be evident that various modifications and changes may be made thereto without departing from the broader spirit and scope of the invention as set forth in the claims that follow. The specification and drawings are accordingly to be regarded in an illustrative manner rather than a restrictive sense.

What is claimed is:

1. A system comprising:
a processor coupled to a memory, the memory storing a compiled software application, the compiled software application including a first plurality of functions and a second plurality of function calls; and
a field programmable gate array (FPGA) coupled to the processor, the FPGA including a compiled user function, the compiled user function executable in response to one of the second plurality of function calls.

2. The system of claim 1, comprising a host computing environment including the processor and the memory, the host computing environment including a host application program interface (API), and wherein the FPGA includes a client API, the host API providing an interface between the compiled software application and the client API, the client API providing an interface between the host API and the compiled user function.

3. The system of claim 2, wherein the host API is configured to pass arguments for the compiled user function to the client API, request execution of the compiled user function, receive notification from the client API that indicate an end of execution of the user function, and retrieve return data from the user function via the client API.

4. The system of claim 3, wherein the client API is configured to receive the arguments passed from the host API, forward the received arguments to the user function, begin execution of the user function on the FPGA, and, upon the end of execution of the user function, configure return data and transmit a signal the host API indicating the end of execution of the user function.

5. The system of claim 1, further comprising a digital signal processor coupled to the FPGA.

6. The system of claim 1, wherein the processor is coupled to the FPGA via direct memory access.

7. The system of claim 1, wherein the processor is coupled to the FPGA via a data bus.

8. The system of claim 7, wherein the data bus is a PCI bus.

9. The system of claim 1, wherein the processor is coupled to the FPGA via a serial port.

10. The system of claim 1, wherein the FPGA is coupled to a source of streaming data.

11. The system of claim 1, wherein the compiled user function is compiled into a bit map file.

12. The system of claim 1, wherein the compiled user function is compiled from an object oriented programming language into a bit map file.

13. The system of claim 1, wherein the compiled user function is compiled from a C programming language into a bit map file.

14. The system of claim 13, wherein the C programming language is handel C.

15. A method for executing a compiled software application, comprising
(a) providing a processor coupled to a memory, the memory including a compiled software application, the compiled software application including a first plurality of functions and a second plurality of function calls, at least one of the second plurality of function calls corresponding to a compiled user function;
(b) executing the first plurality of functions and second plurality of function calls on the processor; and
(c) in response to the at least one of the plurality of function calls, executing the compiled user function on a field programmable gate array (FPGA) coupled to the processor.

16. The method of claim 15, wherein step (b) comprises the steps of
passing arguments for the compiled user function to the FPGA
requesting initiation of the compiled user function;
receiving notification from the FPGA that indicates an end of execution of the compiled user function; and
retrieving return data from the compiled user function from the FPGA.

17. The method of claim 16, wherein step (c) comprises the steps of
receiving the arguments passed from the processor,
forwarding the received arguments to the compiled user function,
executing the compiled user function on the FPGA, and;
upon the end of execution of the compiled user function, configuring the return data and transmitting a notification to the processor indicating the end of execution of the compiled user function.

18. The method of claim 17, wherein the step of executing the compiled user function on the FPGA includes the step of transmitting information to, and receiving information from, a digital signal processor coupled to the FPGA.

19. A method for executing a compiled software application, comprising
(a) in a host computing environment including a compiled software application, the compiled software application including a first plurality of functions and a second plurality of function calls, at least one of the second plurality of function calls corresponding to a compiled user function:
passing arguments for a compiled user function to a Field Programmable Gate Arrary (FPGA) coupled to the host computing environment,
requesting initiation of the compiled user function,
receiving a notification from the FPGA that indicate an end of execution of the compiled user function, and
retrieving return data from the compiled user function via the FPGA;
(b) on the FPGA:
receiving the arguments passed from the host computing environment,
executing of the compiled user function on the FPGA, and
upon the end of execution of the compiled user function, configuring the return data and transmitting the notification to the host computing environment indicating the end of execution of the compiled user function.

20. The method of claim 19, wherein the step of executing the compiled user function on the FPGA includes the step of transmitting information to, and receiving information from, a digital signal processor coupled to the FPGA.

21. A system comprising:
a host computing environment, the host computing environment including a compiled software application, the compiled software application including a first plurality of functions and a second plurality of function calls;
a field programmable gate array (FPGA) coupled to the host computing environment, the FPGA including a compiled user function, the compiled user function corresponding to at least one of the plurality of function calls;
a host application program interface (API) on the host computing environment; and
a client API on the FPGA,
wherein the host API passes arguments for the compiled user function to the client API, requests execution of the compiled user function, receives signals from the client API that indicate an end of execution of the compiled user function, and retrieves return data from the compiled user function via the client API, and
wherein client API receives the arguments passed from the host API, forwards the received arguments to the compiled user function, begins execution of the compiled user function, and, upon the end of execution of the compiled user function, configures the return data and transmits a signal the host API indicating the end of execution of the compiled user function.

22. The system of claim 21, further comprising a digital signal processor coupled to the FPGA.

23. The system of claim 21, wherein the host computing environment is coupled to the FPGA via direct memory access.

24. The system of claim 21, wherein the host computing environment is coupled to the FPGA via a data bus.

25. The system of claim 24, wherein the data bus is a PCI bus.

26. The system of claim 21, wherein the host computing environment is coupled to the FPGA via a serial port.

27. The system of claim 21, wherein the FPGA is coupled to a source of streaming data.

28. The system of claim 21, wherein the compiled user function is compiled into a bit map file.

29. The system of claim 21, wherein the compiled user function is compiled from an object oriented programming language into a bit map file.

30. The system of claim 29, wherein the compiled user function is compiled from a C programming language into a bit map file.

31. A system comprising:
a host computing environment, the host computing environment including a compiled software application, the compiled software application including a first plurality of functions and a second plurality of function calls; and
a field programmable gate array (FPGA) coupled to the host computing environment, the FPGA including a plurality of compiled user functions, a first one of the plurality of compiled user functions being executed in response to one of the second plurality of function calls, and a second one of the plurality of compiled user functions being executed in response to an instruction from the first one of the plurality of compiled user functions.

32. The system of claim 31, wherein the first one of the plurality of compiled user functions has a first mailbox associated therewith and the second one of plurality of compiled users functions has a second mailbox associated therewith.

33. The system of claim 32, wherein the instruction is transmitted from the first mailbox to the second mailbox.

34. The system of claim 31, wherein the FPGA includes a first FPGA coupled to the host computing environment and including the first one of the plurality of compiled user functions, and a second FPGA coupled to the first FPGA and including the second one of the plurality of compiled user functions.

35. A method for providing an interface between a processor and an FPGA, the processor being operable to execute a compiled software application, the compiled software application including a first plurality of functions and a second plurality of function calls, at least one of the second plurality of function calls corresponding to the compiled user function, the method comprising the steps of:
passing arguments for a compiled user function to a Field Programmable Gate Arrary (FPGA) coupled to a processor,
requesting execution of the compiled user function,
receiving a notification from the FPGA that indicates an end of execution of the compiled user function, and
retrieving return data from the compiled user function via the FPGA;

36. A method for providing an FPGA interface to a processor, the processor being operable to execute a compiled software application, the compiled software application including a first plurality of functions and a second plurality of function calls, at least one of the second plurality of function calls corresponding to a compiled user function on an FPGA, the method comprising the steps of:
on the FPGA:
receiving arguments for a compiled user function from the processor,
passing at least a portion of the received arguments to the compiled user function, and
upon receiving an indication of an end of execution of the compiled user function, configuring the return data and transmitting a notification to the processor indicating the end of execution of the compiled user function.

37. A method for executing a compiled software application, comprising
(a) in a host computing environment including a compiled software application, the compiled software application including a first plurality of functions and a second plurality of function calls, at least one of the second plurality of function calls corresponding to a compiled user function:
passing arguments for a plurality of compiled user functions to a Field Programmable Gate Arrary (FPGA) coupled to the host computing environment,
requesting execution of the plurality of compiled user functions,
receiving a notification from the FPGA that indicates an end of execution of one of the compiled user functions,
sending a query to the FPGA requesting identification of the one of the compiled user functions;
receiving a function index corresponding to the one of the compiled user functions from the FPGA, the function index having a corresponding return function address;
sending a read call to the FPGA, the read call including the return function address;
(b) on the FPGA:
receiving the arguments passed from the host computing environment,
executing of the plurality of compiled user functions on the FPGA, and
upon the end of execution of the one of the compiled user functions, configuring the return data and transmitting a notification to the host computing environment indicating the end of execution of the one of the compiled user function;
receiving the query from the host computing environment;
transmitting the function index to the host computing environment;
receiving the read call, and, in response thereto, transmitting the return data to the host computing environment.

38. The method of claim 37, wherein the step of executing the plurality of compiled user functions on the FPGA includes the step of transmitting information to, and receiving information from, a digital signal processor coupled to the FPGA.

39. The method of claim 37, wherein the steps of passing arguments for a plurality of compiled user functions to a Field Programmable Gate Arrary (FPGA) and requesting execution of the plurality of compiled user functions comprises issuing an ExecuteFunctionWait function call.

39. The method of claim 37, wherein the steps of passing arguments for a plurality of compiled user functions to a Field Programmable Gate Arrary (FPGA) and requesting execution of the plurality of compiled user functions comprises issuing an WriteData function call.

40. The method of claim 40, wherein the step of sending a read call includes issuing a ReadData function call.

41. The method of claim 39, wherein the ExecuteFunctionWait function includes a plurality of arguments, the plurality of arguments including FunctionIndex, DataAmountParameters, ParameterDataBuffer, ReturnDataAmount, and ReturnDataBuffer, and wherein FunctionIndex is an address of the user function to be executed in the FPGA, ParameterDataBuffer is a data buffer which contains the arguments to send to the user function to be executed, DataAmountParameters is a size of the ParameterDataBuffer, ReturnDataBuffer is a data buffer used to store the return data from the user function to be executed, and ReturnDataAmount is a size of the return data buffer in bytes.

42. The method of claim 40, wherein the ReadData function includes a Configuration function as an argument, the Configuration function including a plurality of arguments including: DataQuantity, DestinationAddress, and DataBuffer, and wherein DataQuantity is an amount of data to be transferred; DestinationAddress is an index of the one of the plurality of functions to which the data is to be transferred; and DataBuffer is a pointer to a data buffer.

43. The method of claim 35, wherein the interface is divided into a platform independent portion and a platform dependent portion.

44. The method of claim 36, wherein the interface is divided into a platform independent portion and a platform dependent portion.

45. A system comprising:
a processor coupled to a memory, the memory storing a compiled software application, the compiled software application including a first plurality of functions and a second plurality of function calls; and
a gate array coupled to the processor, the gate array including a compiled user function, the compiled user function executable in response to one of the second plurality of function calls.

46. The system of claim 45, wherein the gate array is not reprogrammable.

47. The system of claim 2, wherein the host API includes a functions access database, the functions access database including, for each user function, availability information indicative of an availability of the user function.

48. The system of claim 1, wherein a plurality of the user functions correspond to one of the functions.
